(19) United States
(12) Patent Application Publication
(10) Pub. No.: US 2009/0258164 A1
(43) Pub. Date: Oct. 15, 2009

(54) CARBON STRUCTURE MANUFACTURING DEVICE AND MANUFACTURING METHOD

(76) Inventors: Hiroshi Nakai, Yokohama-shi (JP); Masaru Tachibana, Miura-gun (JP)

Correspondence Address: OSTROLENK FABER GERB & SOFFEN, 1180 AVENUE OF THE AMERICAS, NEW YORK, NY, 100368403, US

(21) Appl. No.: 12/439,321

(22) PCT Filed: Aug. 31, 2007
(86) PCT No.: PCT/JP2007/067062

§ 371 Date: Feb. 27, 2009

(30) Foreign Application Priority Data
Sep. 1, 2006 (JP) 2006-238305

(51) Int. Cl. C23C 16/26; C23C 16/513; C23C 14/34; C23C 16/06

(52) U.S. Cl. 427/576; 118/723 R; 204/298.02; 427/577

(57) ABSTRACT

This invention relates to a carbon structure manufacturing device, which forms carbon structures on a substrate. This manufacturing device comprises a first chamber, which forms a first space accommodating the substrate; a raw material gas supply device, which supplies raw material gas for formation of the carbon structures to the first space; a second chamber, which forms a second space separate from the first space; a gas supply device, which supplies gas for generation of plasma to the second space; a plasma generation device, which generates plasma in the second space; an aperture, connecting the first space and the second space; and, a plasma introduction device, which introduces plasma generated in the second space into the first space via the aperture; the raw material gas is used to form the carbon structures on the substrate. By means of this manufacturing device, when forming carbon structures on the substrate, the occurrence of contamination, foreign matter, and/or the like on electrodes and/or the like can be suppressed, and carbon structures can be formed satisfactorily over a broad area.

### TECHNICAL FIELD

This invention relates to a carbon structure manufacturing device and manufacturing method. This application claims priority from Japanese Patent Application No. 2006-238305, filed with the Japanese Patent Office on Sep. 1, 2006, the contents of which are incorporated herein by reference.

### BACKGROUND ART

Carbon nanowalls, carbon nanotubes, carbon nanofibers, and other carbon structures (carbon nanostructures) are expected to find applications in semiconductor devices, electrodes for fuel cells, and various other fields. Examples of technology relating to methods of manufacture of carbon structures are disclosed in the following patent references,

Patent Reference 1: Japanese Unexamined Patent Application, First Publication No. 2005-307352

Patent Reference 2: Japanese Unexamined Patent Application, First Publication No. 2005-097113

Patent Reference 3: Japanese Unexamined Patent Application, First Publication No. 2006-069816

When for example an electrode positioned in a film deposition chamber is used to generate plasma within the film deposition chamber, and by supplying a hydrocarbon gas or other raw material gas to the film deposition chamber, a carbon structure is grown on a substrate, carbon is supplied to a portion of the electrode, to a portion of the inner wall of the film deposition chamber, or to some member other than the substrate, so that a carbon film is formed on the member.

For example, when a carbon film is formed on the electrode, the state of the plasma generated by the electrode fluctuates, and plasma in the desired state can no longer be generated, so that consequently carbon structures cannot be satisfactorily formed on the substrate.

Further, in addition to the electrode, phenomena may also occur in which large amounts of carbon film are formed on for example a portion of the inner walls of the film deposition chamber in proximity to the electrode. Carbon films formed in this way peel easily, and the peeled carbon film acts as foreign matter. When foreign matter adheres to the substrate, carbon structures cannot be satisfactorily formed on the substrate.

Also, a microwave plasma CVD method in which microwaves are introduced into the film deposition chamber from a window of glass or another nonmetallic material, or a method of forming plasma in a prescribed portion of a reaction vessel of a nonmetallic material such as a quartz glass using an RF coil positioned on the periphery of the reaction vessel, or other methods of discharge without employing an electrode are conceivable, in order to prevent the formation of carbon film on the electrode, the inclusion of elements comprised by the electrode material in the carbon structures as impurities, and/or the like. When such methods are adopted, however, carbon film is formed on the inner face of the window through which microwaves are introduced, or on the inner face of the reaction vessel, so that if the process is continued, power is concentrated in the precipitated portion of the carbon film, and heating occurs. Then, the temperature of this portion rises relative to the environs, and there are concerns that deformation due to fusion of the glass or other nonmetallic material comprised by the window or film deposition chamber, damage due to thermal shock, and/or the like may occur. Also, when rubber O-rings are used as sealing materials for the window and/or the like, if carbon film is formed on the inner face of the window due to the above-described phenomena and power is concentrated, it is anticipated that a heatproof temperature of the sealing material may easily be exceeded. As a result, it may be impossible to maintain a vacuum state, or other serious impediments to the equipment operation may occur.

For these reasons, it has been necessary to frequently clean and/or change the electrode and/or film deposition chamber (reaction vessel) in equipment to form carbon structures.

This invention was devised in light of the above circumstances, and has as an object the provision of a manufacturing device and manufacturing method capable of satisfactorily forming carbon structures over a wide area, suppressing the occurrence of foreign matter and/or the like when forming carbon structures on a substrate. A further object is the provision of a manufacturing device and manufacturing method capable of forming metal film as the underlayer of carbon structures and fine catalyst particles in the same film deposition chamber.

### DISCLOSURE OF THE INVENTION

In order to attain the above objects, in this invention the following configuration is adopted.

A first mode of the invention provides a carbon structure manufacturing device, which forms carbon structures on a substrate using a raw material gas, comprising a first chamber, which forms a first space accommodating the substrate; a raw material gas supply device, which supplies raw material gas for formation of the carbon nanostructures to the first space; a second chamber, which forms a second space separate from the first space; a gas supply device, which supplies gas for generation of plasma to the second space; a plasma generation device, which generates plasma in the second space; an aperture, connecting the first space and the second space; and, a plasma introduction device, which introduces plasma generated in the second space into the first space via the aperture; and wherein the raw material gas is used to form the carbon structures on the substrate by means of the plasma introduced into the first space.

By means of this first mode of the invention, a first space to which a raw material gas for formation of carbon structures is supplied, and a second space in which a plasma is generated, are separately provided, so that the supply of raw material gas to the second space can be suppressed, and formation of carbon film on the electrode or other members comprised by the plasma generation device positioned in the second space can be suppressed. Moreover, there is no electrode and/or the like in the first space, so that the occurrence of phenomena in which large amounts of carbon film are formed in the region of a portion of the inner wall of the first chamber near the electrode can be suppressed. Hence the occurrence of foreign matter can be suppressed, and plasma in the desired state can be used to satisfactorily form carbon structures.

In the manufacturing device of the above mode, a configuration can be adopted in which the pressure is set lower in the first space than in the second space.

By this means, a flow from the second space to the first space can be generated, and plasma in the desired state generated in the second space can be introduced smoothly into the first space. Also, the inflow of matter from the first space into the second space can be suppressed.

In the manufacturing device of the above mode, a configuration can be adopted comprising a magnetic field generation device, positioned in proximity to the aperture, which forms the plasma into a sheet shape in the first space.

By this means, carbon structures can be formed rapidly over a broad region.

In the manufacturing device of the above mode, a configuration can be adopted comprising a sputtering device, having a holding member which holds a target material positioned in the first space, in which the target material is bombarded with ion particles generated based on an inert gas in the plasma introduced into the first space, and in which sputtered particles are discharged from the target material onto the substrate in order to form at least one among a conductive film and fine catalyst particles.

By this means, both operation to form a metal film based on a sputtering method, and operation to form carbon structures based on a plasma CVD method, can be performed in the first space. Hence the desired metal film and/or fine catalyst particles and carbon structures can be formed continuously on the substrate, without for example exposing the substrate to air and/or the like. Further, by executing formation operations using different means (formation operation using a sputtering method, formation operation using a plasma CVD method) in the same space (first space), increased complexity of the manufacturing device structure overall can be alleviated, and the metal film and carbon structures can each be formed smoothly.

A second mode of the invention provides a carbon structure manufacturing method for forming carbon structures on a substrate, comprising an operation of supplying raw material gas to form the carbon structures in a first space in which the substrate is accommodated; an operation of generating plasma in a second space, separate from the first space; an operation of introducing the plasma generated in the second space into the first space, via an aperture; and, an operation of forming the carbon structures on the substrate using the raw material gas, by means of the plasma introduced into the first space.

By means of this second mode of the invention, a first space to which raw material gas is supplied to form carbon structures and a second space to generate plasma are provided separately, so that the supply of raw material gas to the second space can be suppressed, and formation of carbon film on the electrode or other members comprised by the plasma generation device positioned in the second space can be suppressed. Moreover, there is no electrode and/or the like in the first space, so that the occurrence of phenomena in which large amounts of carbon film are formed in the region of a portion of the inner wall of the first chamber near the electrode can be suppressed. Hence the occurrence of foreign matter can be suppressed, and plasma in the desired state can be used to satisfactorily form carbon structures.

In the manufacturing method of the above mode, a configuration can be adopted in which, after forming at least one among the metal film and fine catalyst particles are formed on the substrate, the carbon structures are formed.

By this means, even when for example it is difficult to directly form carbon structures on the substrate, by forming a metal film and/or fine catalyst particles on the substrate, carbon structures can be satisfactorily formed on the substrate on which the metal film and/or fine catalyst particles are formed.

In the manufacturing method of the above mode, a configuration can be adopted in which, after forming the carbon structures on the substrate, fine catalyst particles are formed.

By this means, carbon structures can be put into a desired state.

By means of this invention, the occurrence of contamination, foreign matter, and/or the like on the electrode and other members can be suppressed, and carbon structures can be formed satisfactorily on a large-area substrate.

### BRIEF DESCRIPTION OF THE DRAWINGS

FIG. 1 is a summary view of the configuration of the carbon structure manufacturing device of a first embodiment of the invention;

FIG. 2A is a schematic diagram showing a state in which the quantity of ion particles is adjusted based on the raw material gas supplied to the substrate;

FIG. 2B is a schematic diagram showing a state in which the quantity of ion particles is adjusted based on the raw material gas supplied to the substrate;

FIG. 3 is a summary view of the configuration of the carbon structure manufacturing device of a second embodiment of the invention;

FIG. 4A is a schematic diagram explaining operation of the manufacturing device of the second embodiment of the invention;

FIG. 4B is a schematic diagram explaining operation of the manufacturing device of the second embodiment of the invention;

FIG. 5A is a schematic diagram explaining operation of the manufacturing device of a third embodiment of the invention; and,

FIG. 5B is a schematic diagram explaining operation of the manufacturing device of the third embodiment of the invention.

### DESCRIPTION OF SYMBOLS

1 FIRST CHAMBER

1A FIRST SPACE

2 SECOND CHAMBER

2A SECOND SPACE

3 RAW MATERIAL GAS SUPPLY DEVICE

4 PLASMA GENERATION DEVICE

5 APERTURE

6 PLASMA INTRODUCTION DEVICE

7 SUBSTRATE HOLDER

9 MAGNETIC FIELD GENERATION DEVICE

10 SHEET PLASMA

11 SPUTTERING DEVICE

12 HOLDING MEMBER

FA MANUFACTURING DEVICE

T TARGET MATERIAL

W SUBSTRATE

### BEST MODE FOR CARRYING OUT THE INVENTION

Below, embodiments of the invention are explained referring to the drawings. In the following explanations, an orthogonal XYZ coordinate system is established, and the positional relationships of the various members are explained referring to this orthogonal XYZ coordinate system. The origin is for example taken to be at the plasma source, described below; a prescribed direction in the horizontal plane is made the X-axis direction, the direction perpendicular to the X-axis direction within the horizontal plane is made the Y-axis direction, and the direction perpendicular to both the X-axis direction and to the Y-axis direction (that is, the vertical direction) is made the Z-axis direction. The rotation directions about the X axis, Y axis, and Z axis are respectively θX, θY, and θZ.

### FIRST EMBODIMENT

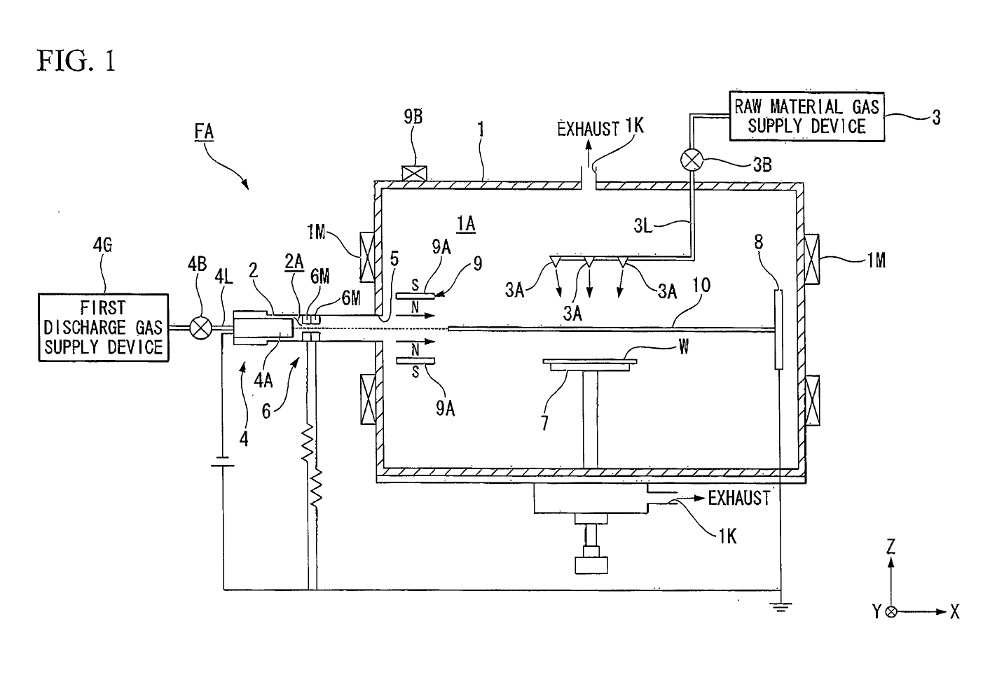

A first embodiment of the invention is explained. FIG. 1 is a summary view of the configuration of the carbon structure manufacturing device FA of the first embodiment of the invention. Carbon structures include so-called carbon nanostructures. Carbon nanostructures include, for example, carbon nanowalls, carbon nanotubes, carbon nanofibers, carbon nanoflakes, and carbon nanosheets.

In this embodiment, an explanation is given for an example in which the manufacturing device FA manufactures carbon nanostructures by forming carbon nanostructures on a substrate W; however, the invention is not limited to such a configuration. The manufacturing device FA can manufacture any structures including carbon. That is, carbon structures (carbon nanostructures) which can be formed by the manufacturing device PA are not limited to those described above, but may be any arbitrary carbon structure (carbon nanostructure).

In FIG. 1, the manufacturing device FA comprises a first chamber 1, forming a first space 1A which accommodates the substrate W; a raw material gas supply device 3, which supplies raw material gas to the first space 1A to form carbon structures; a second chamber 2, forming a second space 2A separate from the first space 1A; a first discharge gas supply device 4G, which supplies gas for discharge to the second space 2A to generate plasma; a plasma generation device 4, comprising a plasma source 4A which generates plasma in the second space 2A; an aperture 5, connecting the first space 1A and the second space 2A; and, a plasma introduction device 6, which introduces plasma generated in the second space 2A into the first space 1A via the aperture 5.

Further, the manufacturing device FA comprises a substrate holder 7 which holds the substrate W. The substrate holder 7 is positioned in the first space 1A, and holds the substrate W such that the substrate W is positioned in the first space 1A. The substrate holder 7 holds the substrate W such that the surface of the substrate W (the face on which carbon structures are formed) is substantially parallel to the XY plane. The substrate holder 7 comprises a temperature adjustment device capable of adjusting the temperature of the held substrate W. A positive or negative potential is applied to the substrate holder 7 (and to the substrate W held by the substrate holder 7).

The substrate W can be formed from any arbitrary material, so long as carbon structures can be formed on the surface thereof; for example, the substrate W can be formed from silicon (Si) or another semiconductor material, glass (quartz) or another insulating material, or nickel (Ni), iron (Fe), cobalt (Co), titanium (Ti), alloys of these, or another conductive material (metal material), and/or the like. The substrate W can also be formed using a conductive ceramic material. In this embodiment, a silicon wafer is used as the substrate W.

The first chamber 1 is a so-called vacuum chamber (film deposition chamber); the first space 1A of the first chamber 1 is set to at least a pressure lower than atmospheric pressure by a vacuum system, not shown. The second chamber 2 is a so-called discharge chamber, positioned outside the first chamber, and forms a second space (discharge space) 2A separate from the first space (film deposition space) 1A. The pressure in the first space 1A is set lower than the pressure in the second space 2A.

The raw material gas supply device 3 supplies raw material gas for formation of carbon structures to the first space 1A in which the substrate W is positioned; as the raw material gas, for example, methane, ethane, ethylene, acetylene, or a hydrocarbon system gas comprising a mixture of these, is supplied. The raw material gas supply device 3 may supply both a hydrocarbon system gas and hydrogen gas. In this embodiment, the raw material gas supply device 3 supplies methane (CH₄) and hydrogen (H₂).

A nozzle member 3A connected to the raw material gas supply device 3 is positioned at a prescribed position of the first space 1A, and the raw material gas delivered from the raw material gas supply device 3 is supplied to the nozzle member 3A via a supply tube 3L. The raw material gas delivered from the raw material gas supply device 3 and flowing in the supply tube 3L is discharged into the first space 1A via the nozzle member 3A. A valve mechanism 3B which can open and close the flow path of this supply tube 3L is installed midway in the supply tube 3L.

An exhaust opening 1K capable of exhaust of gas in the first space 1A is formed at a prescribed position in the first chamber (in this embodiment, at prescribed positions at the top end and bottom end of the first chamber).

A large-diameter air-core coil 1M is positioned at a prescribed position on the outer wall face of the first chamber 1. In this embodiment, the manufacturing device FA has a first coil 1M, positioned on the −X side of the outer wall face so as to surround the second space 2A near the aperture 5, and a second coil IM positioned on the +X side of the outer wall face.

The plasma generation device 4 can generate plasma in the second space 2A, and comprises a plasma gun such as those disclosed in for example Japanese Unexamined Patent Application, First Publication No. 6-119992 or Japanese Unexamined Patent Application, First Publication No. 2001-240957. The plasma generation device 4 comprising a plasma gun can supply generated plasma to the first space 1A.

In this embodiment, the plasma generation device 4 has a plasma source 4A such as that disclosed in Japanese Unexamined Patent Application, First Publication No. 6-119992. The plasma source 4A is positioned in the second space 2A.

The manufacturing device FA comprises a first discharge gas supply device 4G, which supplies gas for discharge to the second space 2A to generate plasma. The first discharge gas supply device 4G supplies discharge gas, to be used in discharge in the plasma generation device 4, to the plasma source 4A positioned in the second space 2A; as the discharge gas, for example, argon gas or another inert gas is supplied. The discharge gas (in this embodiment, argon gas) delivered from the first discharge gas supply device 4G is supplied to the plasma source 4A via the supply tube 4L. A valve mechanism 4B which can open and close the flow path of this supply tube 4L is installed midway in the supply tube 4L.

The plasma source 4A of the plasma generation device 4 creates plasma from the supplied discharge gas by means of arc discharge. The plasma source 4A of the plasma generation device 4 creates plasma from the argon gas supplied from the first discharge gas supply device 4G, generating argon gas plasma.

In this embodiment, the plasma generation device 4 may for example create plasma from the discharge gas by DC discharge utilizing thermal electron emission from a tungsten filament.

The plasma introduction device 6 introduces the plasma generated in the second space 2A by the plasma source 4A of the plasma generation device 4 into the first space 1A via the aperture 5, and comprises a pair of ring-shape electrodes 6M.

An opposing electrode 8 is positioned at a position opposing the electrodes 6M; the plasma electron flow generated in the second space 2A by the plasma generation device 4 is accelerated by the electrodes 6M, and is introduced into (bombards) the first space 1A via the aperture 5.

In this embodiment, the manufacturing device FA comprises a magnetic field generation device 9, positioned close to the aperture 5, which shapes the plasma in the first space 1A into a sheet shape. The magnetic field generation device 9 has a pair of permanent magnets 9A positioned so as to face the aperture 5 therebetween both sides of the aperture 5. The pair of permanent magnets 9A are arranged such that the same poles are in opposition (for example, with N poles in opposition, or with S poles in opposition). Plasma which has been generated by the plasma generation device 4, and which is substantially circular in the YZ plane when passing through the aperture 5, is shaped by the magnetic field generation device 9 into a sheet shape in the YZ plane which is long in the Y-axis direction. In the following explanation, the plasma shaped into a sheet shape by the magnetic field generation device 9 is for convenience called sheet plasma 10.

In this embodiment, permanent magnets 9A shape the plasma into a sheet shape; but the plasma may be shaped by the magnetic field of the coils 1M provided at both ends of the first chamber 1 as well. However, in order to raise the density of the plasma formed in the first space 1A, and to form a field which is uniform over a substrate W of broad area, it is desirable that the sheet-shape plasma be shaped by permanent magnets 9A.

The electrodes 6M are positioned on the −X side of the substrate W held by the substrate holder 7, and the opposing electrode 8 is positioned on the +X side. The sheet plasma 10 advances from the side of the electrodes 6M (the −X side of the first space 1A) toward the side of the opposing electrode 8 (the +X side of the first space 1A), The front surface and rear surface of the sheet plasma 10 are substantially parallel to the XY plane. The nozzle member 3A which supplies raw material gas and the substrate W held by the substrate holder 7 are positioned so as to face the aperture 5 therebetween both sides of the sheet plasma 10.

Next, operation of the manufacturing device FA having the above-described configuration is explained. After the substrate W is held by the substrate holder 7, the temperature of the substrate W is adjusted by the temperature adjustment device. Then, raw material gas to form carbon structures is supplied from the raw material gas supply device 3 to the first space 1A, via the nozzle member 3A. In the plasma generation device 4, discharge gas is supplied from the first discharge gas supply device 4G to the plasma source 4A positioned in the second space 2A, and plasma is generated.

Plasma generated by the plasma generation device 4 in the second space 2A is introduced into the first space 1A, via the aperture 5, by the plasma introduction device 6 comprising the electrodes 6M. The plasma advances through the first space 1A in the +X direction, A magnetic field generation device 9 comprising a permanent magnet 9A is positioned in the first space 1A near the aperture 5, and plasma introduced into the first space 1A spreads out along an XY plane substantially parallel to the surface of the substrate W (the surface on which carbon structures are formed) held by the substrate holder 7, and is converted into sheet plasma 10.

Raw material gas is supplied from the raw material gas supply device 3 into the first space 1A, via the nozzle member 3A, in order to form carbon structures. The sheet plasma 10 within the first chamber 1 excites and ionizes the raw material gas in the first chamber 1. The raw material gas which has been excited and ionized by the plasma introduced into the first space 1A forms carbon structures on the surface of the substrate W held by the substrate holder 7.

As explained above, in this embodiment the plasma source comprising an electrode and/or the like of the plasma generation device 4 to generate plasma is not positioned in the first space 1A of the first chamber 1 used to form carbon structures on a substrate W; rather, the members of the plasma source (electrode) and/or the like comprised by the plasma generation device 4 are positioned in a second space 2A separate from the first space 1A, so that the formation of carbon film on members comprised by the plasma generation device 4 can be suppressed. When a carbon film is formed on the plasma source and/or the like, the state of the plasma generated fluctuates, and there is the possibility that carbon structures in the desired state can no longer be formed on the substrate W. Further, carbon film formed on members other than the substrate W peel easily, and the peeled carbon film acts as foreign matter, so that when this foreign matter adheres to the substrate W, there is the possibility that the performance of carbon structures formed on the substrate is degraded. In this embodiment, a first space 1A to form carbon structures on a substrate W, and a second space 2A in which is positioned a plasma source 4A and/or the like to generate plasma, are provided separately, so that occurrence of the above-described problems can be suppressed.

There is no plasma source and/or the like in the first space 1A to which raw material gas is supplied, and plasma is formed in the second space 2A, so that problems such as formation of large amounts of carbon film in for example local regions on the inner wall surface of the first chamber 1 can be suppressed. For example, when a plasma source to generate plasma is positioned on the inside of the first space 1A of the first chamber 1, depending on the state of the plasma generated based on this plasma source, there is the possibility of formation of large amounts of carbon film in local regions on for example the inner wall face of the first chamber 1 close to the plasma source. For example, when raw material gas is supplied to the plasma generation region in which plasma is generated based on the plasma source, there is the possibility of formation of large amounts of carbon film in local regions of the inner wall face of the first chamber 1 near the plasma generation region. And, even when for example the film deposition chamber is formed as a glass tube and/or the like, an electrode, coil and/or the like is positioned on the outside of this film deposition chamber, and the coil and/or the like positioned outside the film deposition chamber is used to form plasma inside the film deposition chamber, there is the possibility of formation of large amounts of carbon film in a portion of the region of the inner wall face of the film deposition chamber close to the coil. Also, if large amounts of carbon film are formed in local regions on the inner wall face of the first chamber 1, then power is concentrated in these portions only, and there is the possibility that the temperature in these portions may rise excessively. In this case, there is the possibility that a portion of the first chamber 1 may be degraded, or that carbon structures can no longer be formed satisfactorily on the substrate W. In this embodiment, there is no plasma source and/or the like in the first space 1A of the first chamber 1, so that the occurrence of such problems can be suppressed.

Further, in this embodiment the pressure in the first space 1A is set lower than that in the second space 2A, so that a gas flow occurs from the second space 2A toward the first space 1A. By this means, the inflow of raw material gas from the first space 1A into the second space 2A, in which the plasma source 4A is positioned, can be suppressed. That is, in this embodiment, either substantially no raw material gas flows into the plasma generation device 4 which generates plasma, or the inflow is only in very small amounts, so that there is substantially no formation of carbon film on the plasma source 4A and/or the like used to generate plasma.

There is the possibility that carbon film may be formed on the inner wall face of the first chamber 1 also; but the amount is very small. Also, the distance between the inner wall face of the first chamber 1 and the substrate W, and the distance between the inner wall face of the first chamber 1 and the sheet plasma 10, is great, so that adhesion on the substrate W of foreign matter occurring at the inner wall face of the first chamber 1 is suppressed.

There is the possibility of formation of carbon film on the opposing electrode 8 also, but the amounts are very small. And, because the opposing electrode 8 are not electrodes to generate plasma, but are electrodes to guide plasma from the second space 2A to the first space 1A, even if carbon film were to be formed on the opposing electrode 8, problems with fluctuation of the state of the plasma generated would not occur.

Further, in the first space 1A of this embodiment, by generating sheet plasma 10 which is substantially parallel to the surface of the substrate W, uniform carbon structures can be formed smoothly and rapidly over a broad region of the surface of the substrate W under a high plasma density.

Further, in this embodiment, carbon structures can be regularly layered on the substrate W, and carbon structures having desired structures can be manufactured. Hence carbon structures can be formed having excellent field electron emission characteristics, hydrogen absorption characteristics, conductivity in the direction perpendicular to the surface of the substrate W, and/or the like,

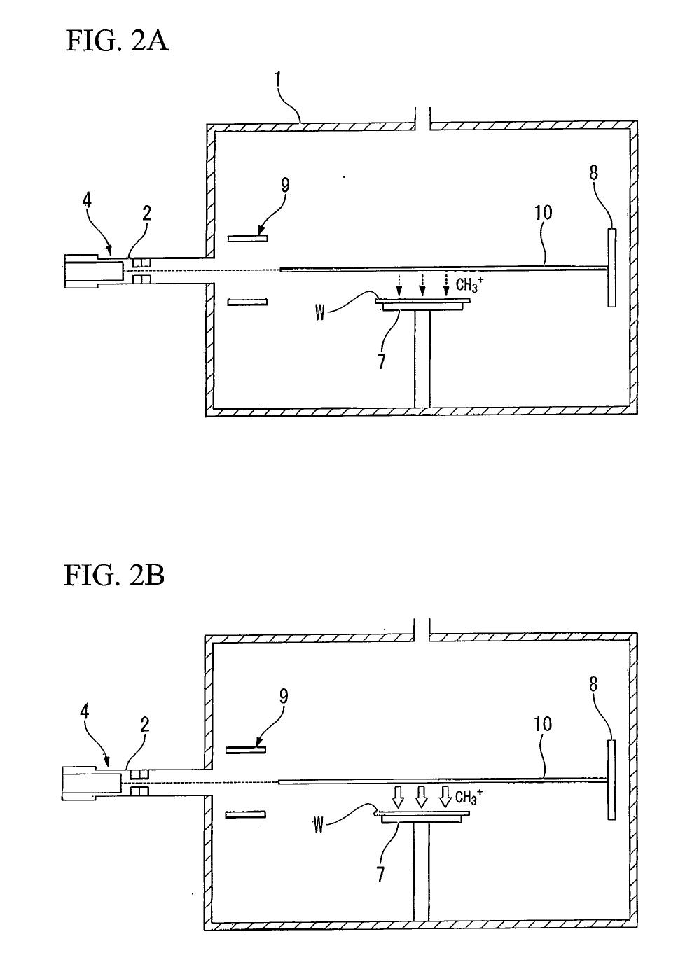

By adjusting the potential of the substrate W, the quantity and energy of ion particles (comprising ion particles based on argon gas and ion particles based on the raw material gas) bombarding (injected into) the substrate W can be adjusted. For example, by adjusting the potential of the substrate W, the supplied quantity of ion particles based on the raw material gas supplied to the substrate W can be reduced, as shown in the schematic diagram of FIG. 2A, and the supplied quantity of ion particles based on the raw material gas supplied to the substrate W can be increased as well, as shown in the schematic diagram of FIG. 2B. Specifically, when a negative potential is applied to the substrate W, by reducing the absolute value of this potential, the supplied quantity of ion particles supplied to the substrate W can be decreased, and by increasing the absolute value of the potential, the supplied quantity of ion particles supplied to the substrate W can be increased.

The energy of incident ions is higher in FIG. 2B than in FIG. 2A, and the energy of incident ions can be adjusted through the negative potential applied to the substrate W. And, by making the potential applied to the substrate W positive, and by adjusting this potential, the inflow of ions to the substrate W can be suppressed, and carbon structures can be formed which have radicals as principal raw materials. In this way, by adjusting the quantity of ions incident on the substrate W, the ion energy, and the quantity of incident radicals, the size of the carbon structures, the size of crystallites which constitute this structures, and the degree of graphitization can be controlled. In addition, electrical conductivity, gas adsorptivity, and other factors can also be controlled.

Also, by moving the substrate holder 7 in the Z-axis direction, the distance between the substrate W and the sheet plasma 10 can be adjusted, and through this adjustment the electric field intensity between the plasma and the substrate W can be adjusted. And, by combining the above-described operations of adjusting the voltage applied to the substrate W and of adjusting the distance between the substrate W and the sheet plasma 10, the ion injection quantity, energy, and radical injection quantity can be controlled satisfactorily.

In this embodiment, the magnetic force generated by electrodes 6M (or by a convergence coil) of the plasma introduction device 6 can be used to effectively introduce plasma generated by the plasma generation device 4 into the first space 1A.

### SECOND EMBODIMENT

Next, a second embodiment of the invention is explained. A characteristic of the second embodiment is the fact that the manufacturing device FA comprises a sputtering device 11, which has a holding member 12 to hold a target material T so as to be positioned in the first space 1A, which bombards the target material T with ion particles generated based on the inert gas in the plasma introduced into the first space 1A, and so causes sputtered particles to be emitted from the target material T in order to form a metal film and/or fine catalyst particles on the substrate W. That is, in the above-described first embodiment, carbon structures are formed based on a so-called plasma CVD method, but in the second embodiment, in addition to the operation of forming carbon structures based on the plasma CVD method, an operation is executed to form metal film and/or fine catalyst particles based on a so-called sputtering method. In the following explanation, constituent portions which are the same as or equivalent to portions in the above-described first embodiment are assigned the same symbols, and explanations thereof are summarized or omitted.

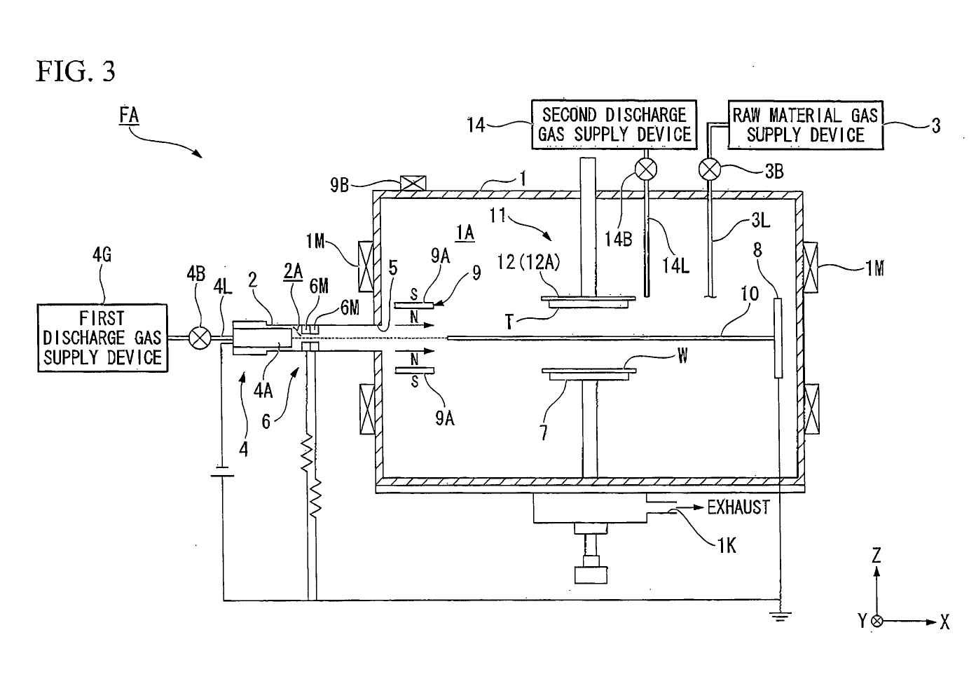

FIG. 3 shows in summary the configuration of the manufacturing device FA of the second embodiment. In FIG. 3, the manufacturing device FA has a sputtering device 11. The sputtering device 11 comprises a holding member 12 having an electrode 12A capable of holding a target material T, and a second discharge gas supply device 14 capable of supplying argon gas or another inert gas to the first space 1A as a discharge gas.

The sputtering device 11 of this embodiment is a DC sputtering device which applies a DC voltage between the target material T and the first chamber 1; however, an RF sputtering device which applies high-frequency waves, or a magnetron sputtering device in which a magnet is positioned on the rear face of the target material T, may be employed.

The holding member 12 comprising an electrode 12A holds the target material T such that the surface of the substrate W held by the substrate holder 7 and the target material T are opposed. In this embodiment, the target material T comprises nickel (Ni), iron (Fe), or another metal.

The inert gas (discharge gas) delivered from the second discharge gas supply device 14 is supplied to the first space 1A via the supply tube 14L. A valve mechanism 14B which can open and close the flow path of this supply tube 14L is installed midway in the supply tube 14L.

The sputtering device 11 supplies argon gas from the second discharge gas supply device 14 as the discharge gas, and plasma is generated near the target material T in the first space 1A, which in this embodiment is a prescribed region on the −Z side of the target material T (a prescribed region between the target material T and the substrate W). In the plasma generation region PU′ in which plasma is generated in the first space 1A, ion particles pl based on this discharge gas are generated. The sputtering device 11 bombards this ion particles p1 onto the target material T, and sputtered particles p2 are emitted from the target material T to form a metal film on the substrate W.

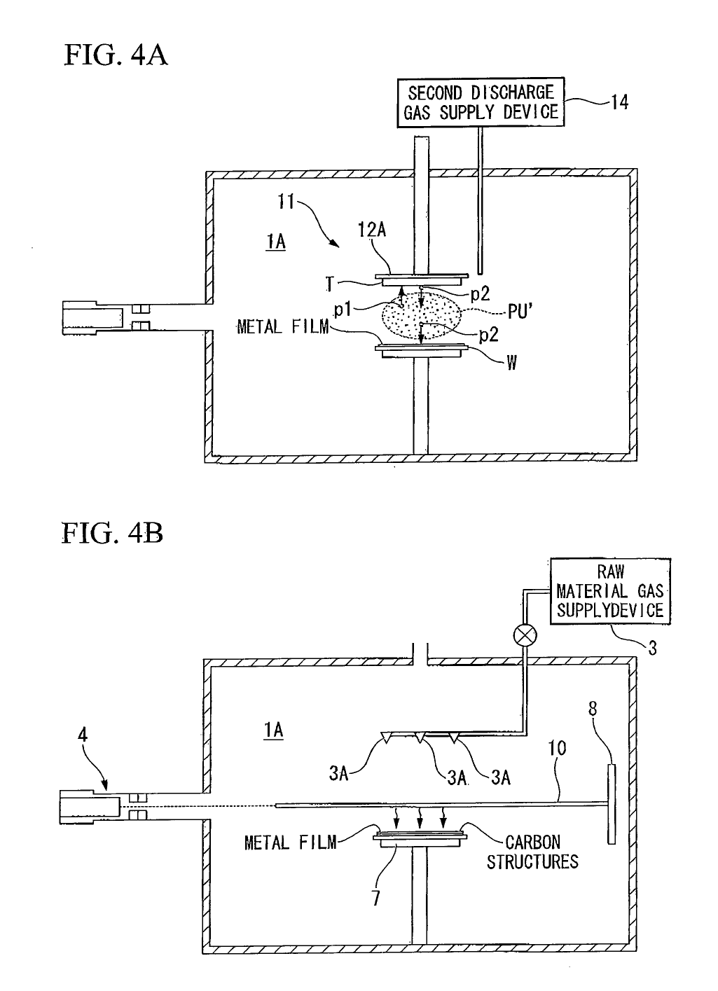

Next, operation of the manufacturing device FA having the above configuration is explained. After the substrate W has been held by the substrate holder 7, the sputtering device 11 performs sputtering of the target material T, as shown in the schematic diagram of FIG. 4A. That is, the manufacturing device FA supplies an inert gas (argon gas) to the first space 1A from the second discharge gas supply device 14, and applies power to the electrode 12A to form a plasma generation region PU′ in a prescribed region in the first space 1A, between the target material T and the substrate W. During sputtering by the sputtering device 11, the plasma generation device 4 does not generate plasma.

By supplying a discharge gas (inert gas) to the plasma generation region PU′, ion particles p1 based on the discharge gas are generated. The target material T is bombarded by the generated ion particles p1. By bombarding the target material T with the ion particles p1, sputtered particles p2 are emitted from the target material T to form the metal film, and a metal film is formed on the substrate W.

After the metal film has been formed on the substrate W by the sputtering device 11, the manufacturing device FA halts operation of the sputtering device 11. As shown in the schematic diagram of FIG. 4, the manufacturing device FA supplies the raw material gas to the first space 1A by means of the raw material gas supply device 3, and generates plasma by means of the plasma generation device 4. In this way, sheet plasma 10 is generated in the first space 1A, and carbon structures are formed on the metal film on the substrate W.

When forming carbon structures, a voltage is not applied to the target material T, the substrate W is heated to a prescribed temperature, the raw material gas is flowed into the first chamber 1, and carbon material is deposited on the metal film on the substrate W. A moveable mechanism for the holding member 12 may be provided so that when raw material gas is supplied and carbon structures are formed on the metal film, the holding member 12 can be moved so as to retract the target material T. In this case, substantially no raw material gas flows into the plasma generation device 4 which generates plasma, or the amount of inflow is minute, so that there is substantially no formation of carbon film on the plasma source 4A and/or the like which generates the plasma.

As explained above, in this embodiment an operation to form a metal film based on a sputtering method, and an operation to form carbon structures based on a plasma CVD method, can be performed within a single first chamber 1. Hence the desired film (structures) can be formed on a substrate W, without for example exposing the substrate to the atmosphere, and while minimizing increased complexity of the structure of the manufacturing device FA overall.

When using carbon structures as electrode materials, films of metals such as copper, aluminum, titanium, nichrome, gold, silver, stainless steel, nickel, and/or the like can be formed, as conductive films which supply electric charge to the carbon structures, and the carbon structures can be formed on the metal film. As the conductive film, in addition to the above-described metal films, ITO, ZnO, and other conductive films can be used.

When the carbon structures to be formed are carbon nanotubes, if forming a film of metal called a catalyst metal (fine catalyst particles), on the substrate W with the purpose of promoting the growth (deposition) of carbon nanotubes, after forming the metal film (catalyst film) on the substrate W in the single first chamber 1A by means of the manufacturing device FA of this embodiment, processing based on a plasma CVD method can be executed to form carbon nanotubes on the catalyst metal.

Apart from catalyst metals, when using a substrate W which does not have good adhesion to carbon structures, after forming a film with good adhesion to carbon structures on the substrate W, by then forming the carbon structures (carbon nanowalls, carbon nanotubes, carbon nanofibers, and/or the like) on the film, the carbon structures can be satisfactorily formed on the substrate W (metal film). Also, as fine catalyst particles, after for example supplying platinum, nickel and/or the like onto the substrate W, the carbon structures can be formed.

In addition to conductive film and fine catalyst particles, after for example forming a film of silicon or another semiconductor on the substrate W, carbon structures may then be formed on the semiconductor film.

### THIRD EMBODIMENT

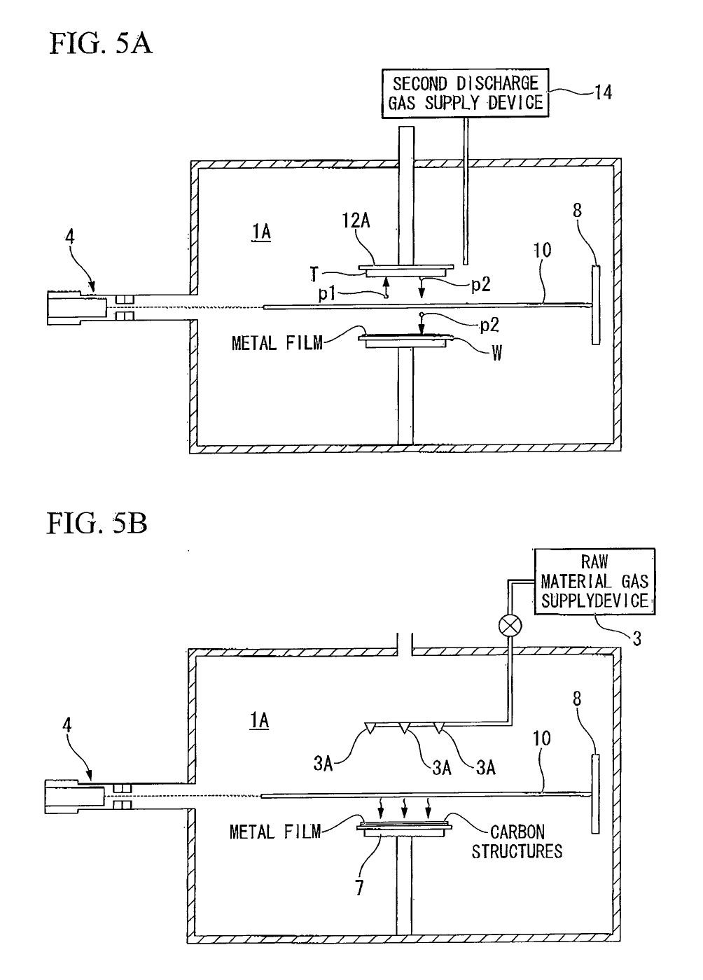

Next, a third embodiment of the invention is explained. In the above-described second embodiment, power is applied to the electrode 12A which holds the target material T, a plasma generation region PU′ is formed in the first space 1A, and a metal film is formed; however, as shown in FIG. 5A, plasma generated by the plasma generation device 4 may be introduced into the first space 1A in which the target material T is positioned, and the introduced plasma (sheet plasma 10) may be used in sputtering of the target material T. By this means, a metal film can be formed on the substrate W.

In this embodiment, the second discharge gas supply device 14 may be omitted. When, for the gas supply quantity from the first discharge gas supply device 4G needed to attain the pressure as necessary to generate plasma in the second space 2A, the pressure in the first space 1A cannot reach the prescribed pressure necessary for sputtering, the second discharge gas supply device 14 may be accessorily used in to adjust the pressure in the first space 1A as necessary for sputtering.

A negative potential relative to the sheet plasma 10 is applied to the target material T, and ion particles p1 generated from the sheet plasma 10 sputter the target material T, so that sputtered particles p2 are emitted from the target material T to form a metal film on the substrate W. At this time, by controlling the temperature of the substrate W, the quantity of sputtered particles p2 incident on the substrate W, the sputtering time, and other factors, the thickness of the metal film, the diameter and distribution of fine catalyst particles, and/or the like can be controlled.

Further, in forming a metal film it is desirable that the width of the target material T (the size in the Y-axis direction) and the width of the sheet plasma 10 (the size in the Y-axis direction) be made substantially the same, in order that the ion particles p1 uniformly bombard a broad region of the target material T. Further, by making the size of the substrate W substantially the same as, or slightly smaller than, the size of the target material T, the film thickness of the metal film formed can be made uniform.

Also, the plasma source 4A can be controlled to increase the quantity of ion particles p1 bombarding the target material T. In order to control the energy with which ion particles p1 strike the target material T, the sputtering voltage applied to the target material T is increased. These can be controlled independently, and differ from a mode such as magnetron sputtering in which only the voltage is controlled, so that the film deposition rate, film quality, and/or the like can be controlled independently.

Next, when forming carbon structures the substrate W is heated to a prescribed temperature without applying a voltage to the target material T, and as shown in FIG. 5B the raw material gas is supplied to the first space 1A, and carbon structures are deposited on the substrate W. At this time, substantially no raw material gas flows into the plasma generation device 4 which generates plasma, or the amount of inflow is minute, so that there is substantially no formation of carbon film in the plasma source 4A which generates plasma. Further, by controlling the current passed to the electrodes 6M, the bias voltage applied to the substrate W, and the distance between the sheet plasma 10 and the substrate W at this time, the quantity of ion particles based on the raw material gas which bombard the substrate W, the ion energies, and the quantity of radicals can be controlled, so that the form and structure of carbon structures can be controlled. In FIG. 5, in order to clarify the operation of forming metal film based on a sputtering method and the operation of forming carbon structures based on a plasma CVD method, the target material T is positioned on the +Z side of the substrate W in FIG. 5A, and the nozzle member 3A is positioned on the +Z side in FIG. 5B; but in the first chamber 1A, a mechanism capable of moving the target material T and nozzle member 3A within the first chamber 1A, and a mechanism for introduction into and retraction from the first chamber 1A, are provided, so that both the sputtering method and the plasma CVD method can be executed. The nozzle member 3A need not be positioned in front of the substrate W, and it is only necessary to be able to introduce the raw material gas into the first chamber 1A.

### FOURTH EMBODIMENT

Next, a fourth embodiment is explained. In the above-described second and third embodiments, after forming a metal film and/or fine catalyst particles on the substrate W, carbon structures are formed; however, fine catalyst particles can be formed after forming carbon structures on the substrate W. An operation of forming a metal film and/or fine catalyst particles based on a sputtering method, such as was explained in the above-described second and third embodiments, can be executed after an operation to form carbon structures on the substrate W. For example, after forming carbon structures on the substrate W, a sputtering method can be used to cause a prescribed material to be incident on the surfaces of the carbon structures. For example, when using carbon structures as electrode materials for fuel cells, platinum, nickel, and/or the like can be supplied, as fine catalyst particles, to carbon structures formed on the substrate W. The supplied platinum, nickel, or other fine catalyst particles are supported by the carbon structures.

In the above-described second through fourth embodiments, when carbon structures are formed, there is the possibility of adhesion of carbon to the surface of the target material T and of inclusion of atoms of the target material T as impurities in the carbon structures. A movement mechanism capable of moving the target material T in the Z-axis direction can be provided, so that by retracting the target material T, adhesion of carbon to the surface of the target material T, and inclusion of atoms of the target material T as impurities in the carbon structures, can be suppressed. In addition, the target material T may be accommodated in a space (chamber) which is blocked from the first space 1A by means of a shutter member, valve mechanism, and/or the like.

### INDUSTRIAL APPLICABILITY

As explained above, by means of this invention, the occurrence of contamination, foreign matter, and/or the like on electrodes and/or the like can be suppressed, and carbon structures can be formed satisfactorily on a large-area substrate.

1. A carbon structure manufacturing device, which forms carbon structures on a substrate, comprising:
a first chamber, which forms a first space accommodating said substrate;
a raw material gas supply device, which supplies raw material gas for formation of said carbon structures to said first space;
a second chamber, which forms a second space separate from said first space;
a gas supply device, which supplies gas for generation of plasma to said second space;
a plasma generation device, which generates plasma in said second space;
an aperture, connecting said first space and said second space; and,
a plasma introduction device, which introduces said plasma generated in said second space into said first space via said aperture;
and wherein said raw material gas is used to form said carbon structures on said substrate by means of said plasma introduced into said first space.

2. The manufacturing device according to claim 1, wherein the pressure is set lower in said first space than in said second space.

3. The manufacturing device according to claim 1, comprising a magnetic field generation device, positioned in proximity to said aperture, which forms said plasma into a sheet shape in said first space.

4. The manufacturing device according to claim 1, comprising a sputtering device, having a holding member which holds a target material positioned in said first space, in which said target material is bombarded with ion particles generated based on an inert gas in the plasma introduced into said first space, and in which sputtered particles are discharged from said target material onto said substrate in order to form at least one among a conductive film and fine catalyst particles.

5. A carbon structure manufacturing method of forming carbon structures on a substrate, comprising:
an operation of supplying raw material gas to form said carbon structures in a first space in which said substrate is accommodated;
an operation of generating plasma in a second space, separate from said first space;
an operation of introducing said plasma generated in said second space into said first space, via an aperture; and,
an operation of forming said carbon structures on said substrate using said raw material gas, by means of said plasma introduced into said first space.

6. The manufacturing method according to claim 5, wherein, after forming at least one among a metal film and fine catalyst particles are formed on said substrate, said carbon structures are formed.

7. The manufacturing method according to claim 5, wherein, after forming said carbon structures on said substrate, fine catalyst particles are formed.
